(19) United States
(12) Patent Application Publication
(10) Pub. No.: US 2025/0015046 A1
(43) Pub. Date: Jan. 9, 2025

(54) SEMICONDUCTOR PACKAGE

(71) Applicant: Samsung Electronics Co., Ltd., Suwon-si (KR)

(72) Inventors: Seho You, Suwon-si (KR); Kyungdon Mun, Suwon-si (KR)

(21) Appl. No.: 18/661,640

(22) Filed: May 12, 2024

(30) Foreign Application Priority Data
Jul. 5, 2023 (KR) 10-2023-0086982

(51) Int. Cl. H01L 25/065; H01L 23/00; H01L 23/31; H01L 23/48; H01L 23/522; H10B 80/00

(52) U.S. Cl. CPC H01L 25/0652; H01L 23/3107; H01L 23/481; H01L 23/5222; H01L 23/5227; H01L 24/16; H01L 24/32; H10B 80/00; H01L 2224/16145; H01L 2224/16225; H01L 2224/32145

(57) ABSTRACT

A semiconductor package includes a package substrate including first and second wirings, a logic chip on the package substrate, electrically connected to the first wiring, and including a first wireless communication element, a chip structure on the logic chip, and including a buffer chip containing first and second through-electrodes, a first connection circuit electrically connected to the first through-electrode, and a second connection circuit electrically connected to the second through-electrode, and a plurality of memory chips stacked on the buffer chip and electrically connected to the first and second through-electrodes, a second wireless communication element within the buffer chip or between the buffer chip and the logic chip, electrically connected to the first connection circuit, and coupled to the first wireless communication element, and a plurality of conductive vertical structures between the chip structure and the package substrate and electrically connecting the second connection circuit and the second wiring.

### CROSS-REFERENCE TO RELATED APPLICATION(S)

This application claims the benefit under 35 U.S.C. § 119 (a) of Korean Patent Application No. 10-2023-0086982, filed on Jul. 5, 2023, in the Korean Intellectual Property Office, the entire disclosure of which is incorporated herein by reference for all purposes.

### BACKGROUND

The present inventive concept relates to semiconductor packages.

As electronic devices become lighter and higher-performance, there is a demand for the development of miniaturized and high-performance semiconductor packages in the semiconductor package field. Accordingly, developments are being made to reduce the area of a semiconductor package in which heterogeneous chips, for example, a logic chip and a memory chip, are mounted together.

### SUMMARY

Example embodiments provide a semiconductor package advantageous for miniaturization and having improved performance.

According to example embodiments, a semiconductor package includes a package substrate including a first wiring and a second wiring; a logic chip on the package substrate, electrically connected to the first wiring of the package substrate, and including a first wireless communication element; a chip structure disposed on the logic chip, and including a buffer chip containing a first through-electrode, a second through-electrode, a first connection circuit electrically connected to the first through-electrode, and a second connection circuit electrically connected to the second through-electrode, and a plurality of memory chips stacked on the buffer chip and electrically connected to the first and second through-electrodes; a second wireless communication element within the buffer chip or between the buffer chip and the logic chip, electrically connected to the first connection circuit, and coupled to the first wireless communication element; and a plurality of conductive vertical structures between the chip structure and the package substrate and electrically connecting the second connection circuit and the second wiring.

According to example embodiments, a semiconductor package includes a chip structure including a buffer chip containing a first through-electrode, a second through-electrode, first lower surface pads, and a first connection circuit electrically connecting the second through-electrode and the first lower surface pads, and a plurality of memory chips stacked on the buffer chip and electrically connected to the first through-electrode and the second through-electrode; a logic chip below the buffer chip to expose the first lower surface pads; a package substrate below the buffer chip and the logic chip, and including a first wiring electrically connected to the logic chip and a second wiring electrically connected to the buffer chip; a first wireless communication element disposed within the chip structure or between the chip structure and the logic chip, and electrically connected to the first through-electrode; a second wireless communication element within the logic chip and coupled to the first wireless communication element; an encapsulant covering at least portions of the chip structure, the logic chip, and the package substrate respectively; and a plurality of conductive vertical structures extending within the encapsulant and electrically connecting the first lower surface pads and the second wiring.

According to example embodiments, a semiconductor package includes a package substrate including a first wiring and a second wiring; a logic chip on the package substrate and electrically connected to the first wiring of the package substrate; a chip structure on the logic chip, and including a memory circuit, and a first through-electrode and a second through-electrode electrically connected to the memory circuit; a first wireless communication element disposed within the logic chip; a second wireless communication element below the chip structure, electrically connected to the first through-electrode, and overlapping the first wireless communication element in a vertical direction; and a conductive vertical structure electrically connecting the second through-electrode of the chip structure and the second wiring of the package substrate.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a plan view of a semiconductor package according to an example embodiment;

FIG. 2 is a cross-sectional view illustrating a cut along line I-I′ of FIG. 1;

FIG. 3 is a cross-sectional view illustrating a semiconductor package according to an example embodiment;

FIGS. 4 to 8 are cross-sectional views schematically illustrating a process of manufacturing a semiconductor package according to an example embodiment;

FIG. 9 is a cross-sectional view illustrating a semiconductor package according to an example embodiment;

FIGS. 10 to 15 are cross-sectional views schematically illustrating a process of manufacturing a semiconductor package according to an example embodiment;

FIG. 16 is a cross-sectional view illustrating a semiconductor package according to an example embodiment;

FIG. 17 is a plan view of a semiconductor package according to an example embodiment;

FIG. 18 is a cross-sectional view illustrating a section taken along line II-II′ of FIG. 17; and

FIG. 19 is a cross-sectional view illustrating a semiconductor package according to an example embodiment.

### DETAILED DESCRIPTION

Hereinafter, example embodiments will be described with reference to the attached drawings. Unless otherwise specified, in this specification, terms such as “upper portion”, “upper surface”, “lower portion”, “lower surface”, “side”, “side surface” and the like are based on the drawings, and in reality, may vary depending on the direction in which the components are disposed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

It will be understood that, although the terms first, second, third etc. may be used herein to describe various elements, components, regions, layers and/or sections, these elements, components, regions, layers and/or sections should not be limited by these terms. Unless the context indicates otherwise, these terms are only used to distinguish one element, component, region, layer or section from another element, component, region, layer or section, for example as a naming convention. Thus, a first element, component, region, layer or section discussed below in one section of the specification could be termed a second element, component, region, layer or section in another section of the specification or in the claims without departing from the teachings of the present invention. In addition, in certain cases, even if a term is not described using “first,” “second,” etc., in the specification, it may still be referred to as “first” or “second” in a claim in order to distinguish different claimed elements from each other.

Terms such as “same,” “equal,” “planar,” or “coplanar,” as used herein, encompass near identicality including variations that may occur, for example, due to manufacturing processes. The term “substantially” may be used herein to emphasize this meaning, unless the context or other statements indicate otherwise.

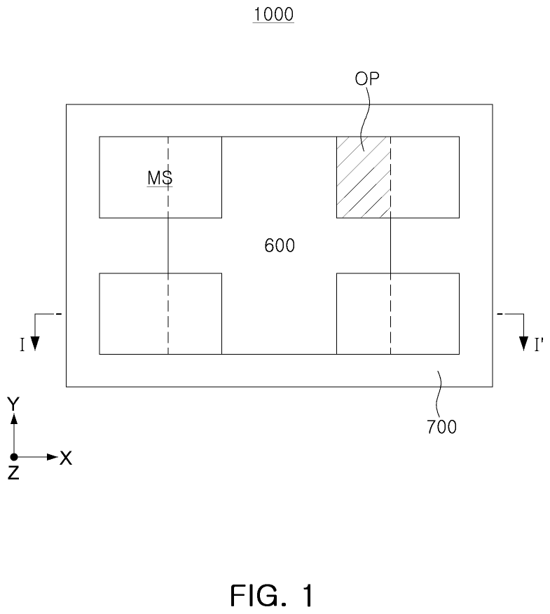

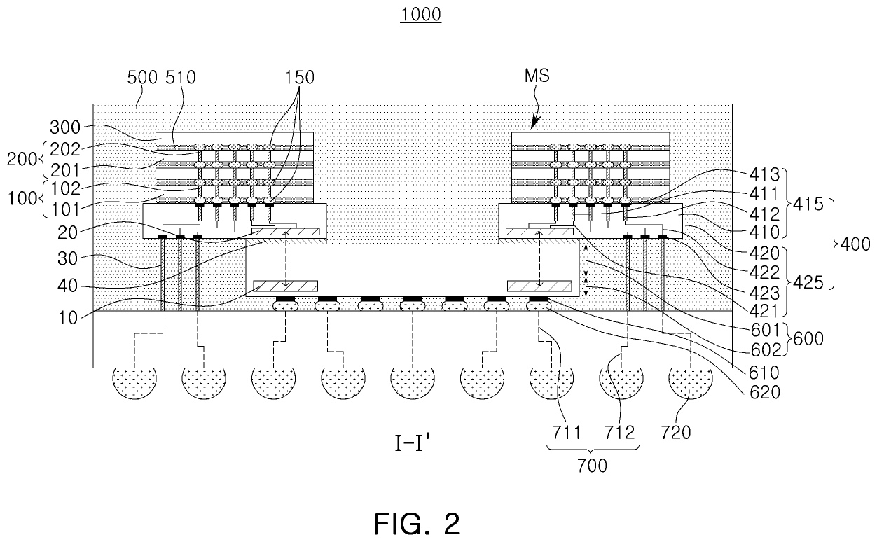

FIG. 1 is a top view of a semiconductor package 1000 according to an example embodiment. FIG. 2 is a cross-sectional view illustrating a cut along line I-I′ of FIG. 1.

Referring to FIGS. 1 and 2, the semiconductor package 1000 of an example embodiment may include a package substrate 700, at least one chip structure (MS) (or ‘memory chip structure (MS)’), and a logic chip 600 (or ‘processor chip 600’).

The package substrate 700 may be a support substrate on which the logic chip 600 and the chip structure (MS) are mounted, and may be a substrate for a semiconductor package, including a printed circuit board (PCB), a ceramic substrate, a glass substrate, a tape wiring substrate, or the like. The body of the package substrate 700 may contain different materials depending on the type of substrate. For example, when the package substrate 700 is a printed circuit board, the body may have a form of a body copper clad laminate or an additional wiring layer laminated on one or both sides of the copper clad laminate.

The package substrate 700 may include first and second wirings 711 and 712. The first and second wirings 711 and 712 may form an electrical path connecting the lower surface and the upper surface of the package substrate 700. The first and second wirings 711 and 712 may be formed of or include a metal material, for example, at least one of copper (Cu), aluminum (Al), nickel (Ni), silver (Ag), gold (Au), platinum (Pt), tin (Sn), lead (Pb), titanium (Ti), chromium. (Cr), palladium (Pd), indium (In), zinc (Zn), and carbon (C), or an alloy containing two or more metals thereof. External connection terminals 720 electrically connected to the first and second wirings 711 and 712 may be disposed below the package substrate 700. The external connection terminals 720 may be formed of or include tin (Sn), indium (In), bismuth (Bi), antimony (Sb), copper (Cu), silver (Ag), zinc (Zn), lead (Pb) and/or alloys thereof. Pads connected to the first and second wirings 711 and 712 may be disposed on the upper and lower surfaces of the package substrate 700, respectively.

The logic chip 600 may include a first region 601 and a second region 602. The logic chip 600 may be mounted on the package substrate 700 through lower surface pads 610 disposed on the lower surface of the logic chip 600 and connection bumps 620 disposed below the lower surface pads 610. Each connection bump 620 may contact a corresponding one of the lower surface pads 610. The logic chip 600 may be electrically connected to the first wiring 711 of the package substrate 700 through the connection bumps 620 disposed below the lower surface pads 610. The logic chip 600 may include, for example, a central processor (CPU), a graphics processor (GPU), a field programmable gate array (FPGA), a digital signal processor (DSP), a cryptographic processor, a microprocessor, a microcontroller, an analog-to-digital converter, an application-specific integrated circuit (ASIC), and the like.

The first region 601 may be disposed on the second region 602, and the first region 601 may include a semiconductor element such as silicon or germanium (Ge), or may be a semiconductor substrate containing a compound semiconductor such as silicon carbide (SiC), gallium arsenide (GaAs), indium arsenide (InAs), or indium phosphide (InP).

The second region 602 may be disposed below the first region 601, and the second region 602 may include a first wireless communication element 10 and an integrated circuit (not illustrated) electrically connected to first wireless communication element 10. The integrated circuit may be an integrated circuit including central processor (CPU), graphics processor (GPU), field programmable gate array (FPGA), digital signal processor (DSP), cryptographic processor, microprocessor, microcontroller, analog-to-digital converter, application-specific integrated circuit (ASIC), and the like. The integrated circuit connected to the first wireless communication element 10 may be electrically connected to the first wiring 711 of the package substrate 700 through the lower surface pads 610 and the connection bumps 620 disposed below the logic chip 600.

The chip structure MS may include a plurality of semiconductor chips 100, 200, and 300 on a buffer chip 400, bump structures 150, and at least one adhesive layer 510.

Each of the plurality of semiconductor chips 100, 200, and 300 may be comprised of memory chips or memory elements that store or output data based on address commands and control commands received from the buffer chip 400. For example, the plurality of semiconductor chips 100, 200, and 300 may include volatile memory devices such as DRAM and SRAM, or non-volatile memory devices such as PRAM, MRAM, FeRAM, or RRAM. Among the plurality of semiconductor chips 100, 200, and 300, an uppermost semiconductor chip 300 (hereinafter referred to as ‘third semiconductor chip’) does not include a through-via.

The plurality of semiconductor chips 100, 200 and 300 may include a first semiconductor chip 100, at least one second semiconductor chip 200, and a third semiconductor chip 300 sequentially stacked on the buffer chip 400.

The first semiconductor chip 100 may include a substrate 101 and a plurality of through-electrodes 102 extending through the substrate 101. The second semiconductor chip 200 may include a substrate 201 and a plurality of through-electrodes 202 extending through the substrate 201. Each of the substrates 101 and 201 may be formed of or include, for example, a semiconductor element such as silicon or germanium (Ge), and may include a compound semiconductor such as silicon carbide (SiC), gallium arsenide (GaAs), indium arsenide (InAs), or indium phosphide (InP). The through-electrodes 102 and 202 that are stacked on one another may be connected by bump structures 150. For example, the bump structures 150 may contact corresponding pairs of the through-electrodes 102 and 202.

The buffer chip 400 may include a first layer 415 and a second layer 425. For example, the buffer chip 400 may be a semiconductor chip including a plurality of logic elements and/or memory elements in the second layer 425. Therefore, the buffer chip 400 may transmit externally, signals from the plurality of semiconductor chips 100, 200, and 300 stacked thereon, and additionally, may transmit signals and power from external sources to the plurality of semiconductor chips 100, 200, and 300. The buffer chip 400 may perform both logic and memory functions through logic elements and memory elements together, but depending on an example embodiment, the buffer chip 400 may include only logic elements and perform only logic functions.

The first layer 415 may be disposed on the second layer 425, and the first layer 415 may include a substrate 410, first and second through-electrodes 411 and 412, and upper pads 413.

The substrate 410 may be formed of or include, for example, a semiconductor element such as silicon or germanium (Ge), and may include a compound semiconductor such as silicon carbide (SiC), gallium arsenide (GaAs), indium arsenide (InAs), or indium phosphide (InP).

The upper pads 413 may be disposed in an upper portion of the first layer 415 (or ‘buffer chip 400’) such that the upper surfaces thereof are exposed. For example, the upper surfaces of the upper pads 413 may be coplanar with an upper surface of the first layer 415. The upper pads 413 may be formed of or include, for example, at least one of aluminum (Al), copper (Cu), nickel (Ni), tungsten (W), platinum (Pt), and gold (Au).

The first and second through-electrodes 411 and 412 may penetrate the substrate 410 in the vertical direction (Z-direction). The first and second through-electrodes 411 and 412 may be electrically connected to the plurality of semiconductor chips 100, 200, and 300. Each of the first and second through-electrodes 411 and 412 may include a conductive plug and a barrier film surrounding the conductive plug. The conductive plugs may be formed of or include a metallic material, such as tungsten (W), titanium (Ti), aluminum (Al), or copper (Cu). The conductive plug may be formed by a plating process, a PVD process, or a CVD process. The barrier film may be formed of or include titanium (Ti), titanium nitride (TiN), tantalum (Ta), or tantalum nitride (TaN), and may be formed by a plating process, PVD process, or CVD process. Between the side surfaces of the first and second through-electrodes 411 and 412 and the substrate 410, a side insulating film (not illustrated) containing an insulating material (e.g., a High Aspect Ratio Process (HARP) oxide) such as silicon oxide, silicon nitride, silicon oxynitride or the like may be formed.

The second layer 425 may be disposed below the first layer 415, and the second layer 425 may include an insulating layer 420, first and second connection circuits 421 and 422, first lower pads 423, and a second wireless communication element 20.

The insulating layer 420 may be formed of or include silicon oxide, silicon nitride, silicon oxynitride, and the like.

The first connection circuit 421 may electrically connect the first through-electrodes 411 and the second wireless communication element 20. The second connection circuit 422 may electrically connect the second through-electrodes 412 and the first lower pads 423. The first and second connection circuits 421 and 422 may be formed of or include a material the same as or similar to a material of the upper pads 413. However, the materials of the upper pads 413 and the first and second connection circuits 421 and 422 are not limited to the above materials.

The first lower pads 423 may be disposed in a lower portion of the second layer 425 (or ‘buffer chip 400’) such that the lower surface thereof is exposed, and may be formed of or include a material the same as or similar to that of the upper pad 413. However, the materials of the upper pad 413 and first lower pad 423 are not limited to the above materials. In example embodiments, a lower surface of the first lower pads 423 may be coplanar with a lower surface of the second layer 425.

The second wireless communication element 20 may be wirelessly coupled to the first wireless communication element 10. The first wireless communication element 10 and the second wireless communication element 20 may be configured to transmit and receive signals using inductive coupling or capacitive coupling. For example, the first wireless communication element 10 and the second wireless communication element 20 may respectively include a first conductive pattern (not illustrated) and a second conductive pattern (not illustrated) provided for wireless communication. The first conductive pattern may include a conductive receiving pattern that receives a signal such as current and the like from the second conductive pattern, and the second conductive pattern may include a conductive transmission pattern that transmits a signal and the like such as current to the first conductive pattern. Additionally, the first conductive pattern may include a conductive transmission pattern that transmits a signal such as current from the second conductive pattern, and the second conductive pattern may include a conductive receiving pattern that receives a signal such as current from the first conductive pattern.

In the case in which the first wireless communication element 10 and the second wireless communication element 20 are connected by inductive coupling, the first conductive pattern may include a first circuit electrically connected to the first connection circuit 421 and a first coil electrically connected to the first circuit, and the second conductive pattern may include a second circuit and a second coil electrically connected to the second circuit. The second coil of the second wireless communication element 20 may be disposed to face the first coil of the first wireless communication element 10. A current induced by a current flowing in the second coil through the second circuit may flow through the first coil and the first circuit connected to the first coil.

In the case in which the first wireless communication element 10 and the second wireless communication element 20 are connected by capacitive coupling, the first conductive pattern includes a first circuit electrically connected to the first connection circuit and a first electrode electrically connected to the first circuit, and the second conductive pattern may include a second circuit and a second electrode electrically connected to the second circuit. The second electrode of the second wireless communication element 20 may be disposed to face the first electrode of the first wireless communication element 10. A potential difference may occur between the first electrode and the second electrode due to the current flowing in the second electrode through the second circuit. Due to the potential difference, an induced current may flow in the first circuit connected to the first electrode.

Referring to FIG. 1, at least a portion of each of the chip structures MS may be disposed to have a portion OP (or ‘overlapping portion OP’) that overlaps at least a portion of the logic chip 600. In the overlapping portion OP, at least a portion of the lower surface of the buffer chip 400 of each chip structure MS and at least a portion of the upper surface of the logic chip 600 may be adhered by an adhesive layer 40. The adhesive layer 40 may be formed of or include an adhesive polymer material such as a polymer binder resin, an epoxy resin, a phenol-type epoxy curing agent, a curing catalyst, a silane coupling agent or the like, but the present inventive concept is not limited thereto. The adhesive layer 40 may be in the form of paste or film, but is not limited thereto.

A plurality of conductive vertical structures 30 may be disposed between each of the chip structures MS and the package substrate 700. The plurality of conductive vertical structures 30 may respectively extend vertically from the upper surface of the package substrate 700 to the first lower pads 423 of the buffer chip 400. The plurality of conductive vertical structures 30 may electrically connect the chip structures MS and the package substrate 700. The plurality of conductive vertical structures 30 may electrically connect the second wiring 712 of the package substrate 700 and the second connection circuit 422 of the buffer chip 400. The conductive vertical structures 30 may include a material with high electrical conductivity. For example, the conductive vertical structures 30 may be formed of or include a metal including gold (Au), silver (Ag), copper (Cu), or alloys thereof, but the present inventive concept is not limited thereto.

The adhesive layers 510 may surround bump structures 150 disposed between the plurality of semiconductor chips 100, 200, and 300, and may fix the plurality of semiconductor chips 100, 200, and 300 onto the buffer chip 400. At least portions of the respective adhesive layers 510 may protrude from the side surfaces of the plurality of semiconductor chips 100, 200, and 300 to form protrusions. The adhesive layers 510 may be Non Conductive Film (NCF), but are not limited thereto, and for example, may include all types of polymer films capable of a thermocompression process.

The logic chip 600, at least one chip structure (MS), the adhesive layer 40, and the plurality of conductive vertical structures 30 may be sealed on the package substrate 700 by an encapsulant 500. For example, the encapsulant 500 may be formed of an insulating material such as Epoxy Molding Compound (EMC), but the material of the encapsulant 500 is not particularly limited.

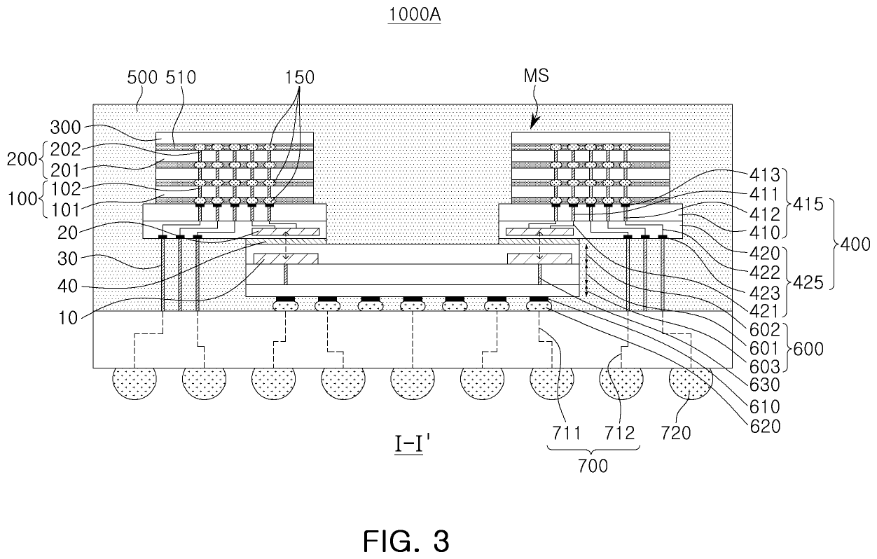

FIG. 3 is a cross-sectional view illustrating a semiconductor package 1000A according to an example embodiment.

Referring to FIG. 3, the semiconductor package 1000A of an example embodiment may have the same or similar features as those described with reference to FIGS. 1 and 2, except that the logic chip 600 includes a third through-electrode 630.

In an example embodiment, the logic chip 600 may include a first region 601, a second region 602, and a third region 603.

The first region 601 may be a semiconductor substrate containing a semiconductor element such as silicon or germanium (Ge), or a compound semiconductor such as silicon carbide (SiC), gallium arsenide (GaAs), indium arsenide (InAs), or indium phosphide (InP). The first region 601 may be a portion of a silicon wafer used in manufacturing semiconductor devices.

The second region 602 may be disposed on the first region 601, and the second region 602 may include a first wireless communication element 10 and a dielectric layer covering the first wireless communication element 10. The dielectric layer may be formed of or include at least one of silicon oxide, silicon nitride, and silicon oxynitride. In some embodiments, the second region 602 may further include a backside wire connected to the first wireless communication element 10, for example, connecting the first wireless communication element 10 and the third through-electrode 630.

The third region 603 may be disposed below the first region 601, and the third region 603 may be an area in which an integrated circuit is formed. The integrated circuit may be electrically connected to the first wireless communication element 10 by a third through-electrode 630 penetrating the first region 601. The integrated circuit may include a central processor (CPU), a graphics processor (GPU), a field programmable gate array (FPGA), a digital signal processor (DSP), a cryptographic processor, a microprocessor, a microcontroller, an analog-to-digital converter, an application-specific integrated circuit (ASIC), and the like. The integrated circuit may be electrically connected to the first wiring 711 of the package substrate 700 through the lower surface pads 610 and the connection bumps 620 disposed below the logic chip 600.

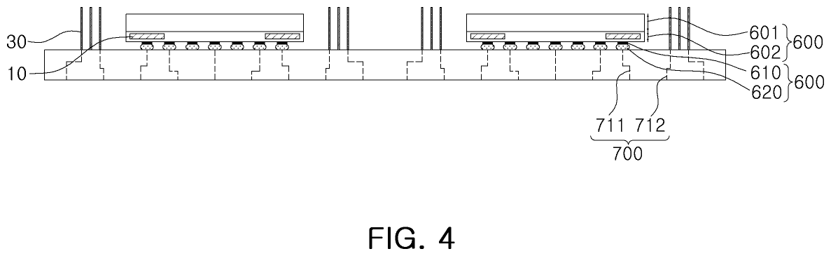

FIGS. 4 to 8 are cross-sectional views schematically illustrating the manufacturing process of a semiconductor package according to an example embodiment.

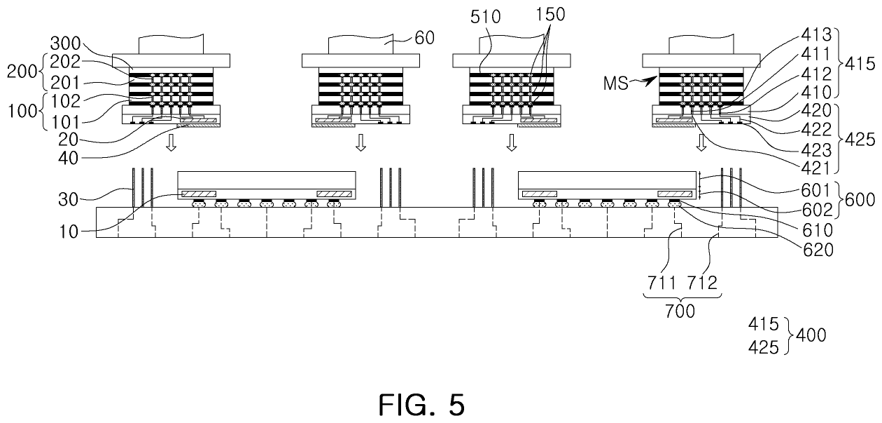

Referring to FIG. 4, a ‘first preliminary package structure’ may be provided in a face-down form. The first preliminary package structure may include a package substrate 700 that includes first and second wirings 711 and 712 and extends laterally, and a plurality of logic chips 600 including the first wireless communication element 10 may be disposed on one surface of the package substrate 700 to be electrically connected to the first wiring 711. The conductive vertical structures 30 may be formed to be electrically connected to the second wiring 712 of the package substrate 700. The conductive vertical structures 30 may be pillar-shaped structures, and in this case, the conductive vertical structures 30 may be formed to extend in a direction perpendicular to the upper surface of the package substrate 700. The upper surface level of the conductive vertical structures 30 may be formed to be higher than the upper surface level of the logic chip 600. The difference between the upper surface levels of the conductive vertical structures 30 and the logic chip 600 may be the thickness of an adhesive layer 40 disposed on one side of the logic chip 600, when referring to FIG. 5. In some embodiments, an upper surface of the adhesive layer 40 may be at the same vertical level as upper surfaces of the conductive vertical structures 30. For example, upper surfaces of the adhesive layer 40 and the conductive vertical structures 30 may be coplanar.

Referring to FIG. 5, the chip structures MS may be placed by a bonding head 60 to overlap at least a portion of the logic chip 600. In this case, the chip structures MS may be provided with the adhesive layer 40 formed in a portion in which the chip structures MS respectively overlap the logic chip 600. For example, the adhesive layer 40 may be formed on at least portions of the lower surfaces of the chip structures MS (or the lower surface of the ‘buffer chip 400’), but the present inventive concept is not limited thereto. For example, the logic chip 600 may be provided with the adhesive layer 40 formed in a portion that overlaps the chip structures MS. In this case, the adhesive layer 40 may be formed on at least a portion of the upper surface of the logic chip 600. In the overlapping part above, the second wireless communication element 20 of the chip structures MS may be disposed to vertically overlap the first wireless communication element 10 of the logic chip 600 and face each other.

The chip structures MS may be placed on the conductive vertical structure 30 by the bonding head 60. In detail, the first lower pads 423, of which lower surfaces are exposed, may be placed to contact the upper surfaces of the conductive vertical structures 30. When the first lower pads 423 and the conductive vertical structures 30 are formed of copper (Cu), a temperature of 300° C. to 500° C. or lower is applied to form copper (Cu)-copper (Cu) bonding between the lower surfaces of the first lower pads 423 and the upper surfaces of the conductive vertical structures 30.

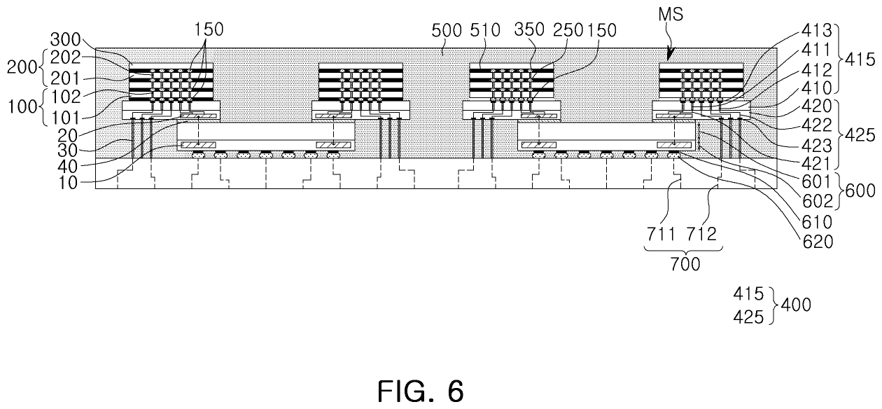

Referring to FIG. 6, on the package substrate 700, the encapsulant 500 surrounding the logic chip 600, the plurality of chip structures MS, the plurality of conductive vertical structures 30, and the adhesive layer 40 may be disposed.

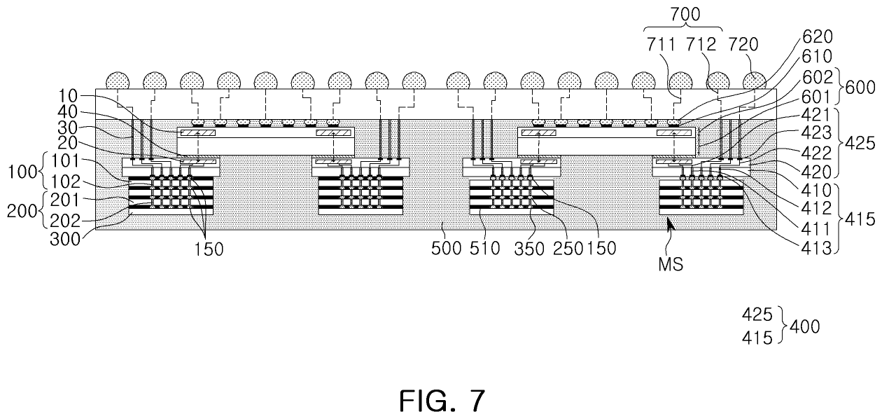

Referring to FIG. 7, the ‘first preliminary package’ surrounded by the encapsulant 500 may be provided to be face-up, and external connection terminals 720 that are electrically connected to the first and second wirings 711 and 712 of the package substrate 700, may be attached.

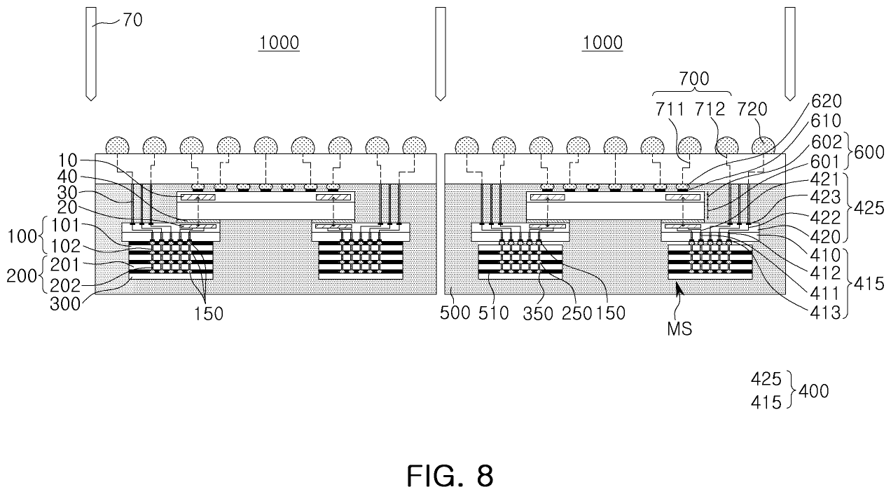

Referring to FIG. 8, the back-side of the package substrate 700 may be cut in a vertical direction using a cutter 70 and may be separated into a plurality of semiconductor packages 1000.

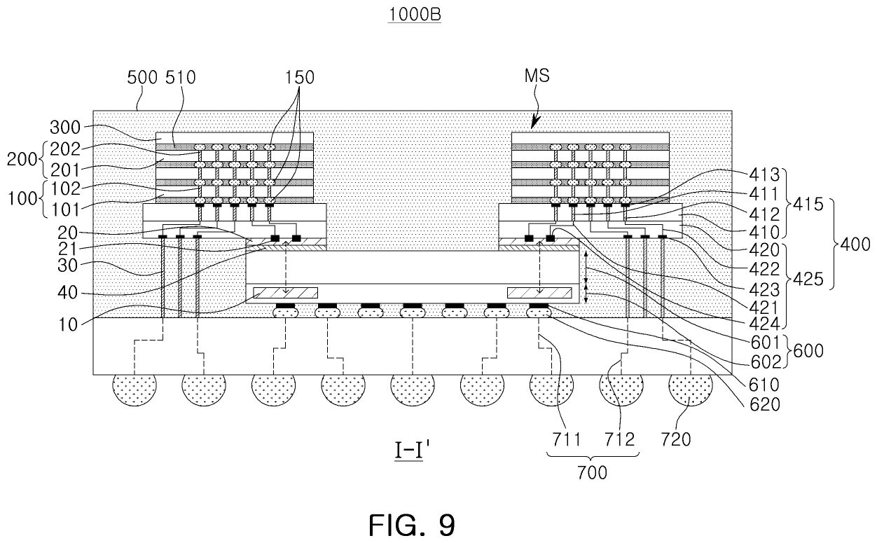

FIG. 9 is a cross-sectional view illustrating a semiconductor package 1000B according to an example embodiment.

Referring to FIG. 9, the semiconductor package 1000B of an example embodiment may have the same features as those described with reference to FIGS. 1 and 2, except that a second wireless communication element 20 is disposed between a chip structure MS and a logic chip 600.

The second layer 425 of the buffer chip 400 may include an insulating layer 420, first and second connection circuits 421 and 422, first lower pads 423, and second lower pads 424. As described above, the insulating layer 420, the first and second connection circuits 421 and 422, and the first lower pads 423 of the second layer 425 may have the same characteristics as the insulating layer 420, the first and second connection circuits 421 and 422, and the first lower pads 423 described with reference to FIGS. 1 and 2.

Referring to FIG. 9, the second lower pads 424 may be disposed in a lower portion of the second layer 425 (or ‘buffer chip 400’) such that the lower surface thereof is exposed. For example, lower surfaces of the second lower pads 424 may be coplanar with a lower surface of the second layer 425. The second lower pads 424 may include a material the same as that of the upper pads 413 and the first lower pads 423, but is not limited thereto.

The second connection circuit 422 may electrically connect the second through-electrodes 412 and the second lower pads 424. The second connection circuit 422 may include a material to the same as that of the upper pads 413 and the first and second lower pads 423 and 424, but is not limited thereto.

The second wireless communication element 20 may be disposed on the chip structure MS (or the lower surface of the ‘buffer chip 400’) and the logic chip 600. The second wireless communication element 20 of this embodiment may be a semiconductor chip on which patterns for wireless communication are formed. For example, the second wireless communication element 20 may include a second conductive pattern (not illustrated) of transmitting and receiving a signal with the first conductive pattern (not illustrated) of the first wireless communication element 10. The upper portion of the second wireless communication element 20 of this embodiment may include front pads 21 for electrically connecting the second conductive pattern to the first through-electrode 411. The second wireless communication element 20 may further include a wiring pattern connecting the second conductive pattern and the front pads 21. The front pads 21 with upper surfaces exposed may be disposed to contact the second lower pads 424 with lower surfaces exposed.

An adhesive layer 40 may be disposed between the logic chip 600 and the second wireless communication element 20. The second wireless communication element 20 may be attached to at least a portion of the upper surface of the logic chip 600 by an adhesive layer 40. The material of the adhesive layer 40 is the same as that described with reference to FIGS. 1 and 2.

The logic chip 600, at least one memory chip structure (MS), the adhesive layer 40, the plurality of conductive vertical structures 30, and the second wireless communication element 20 may be sealed on the package substrate 700 with an encapsulant 500. The material of the encapsulant 500 is the same as that described with reference to FIGS. 1 and 2.

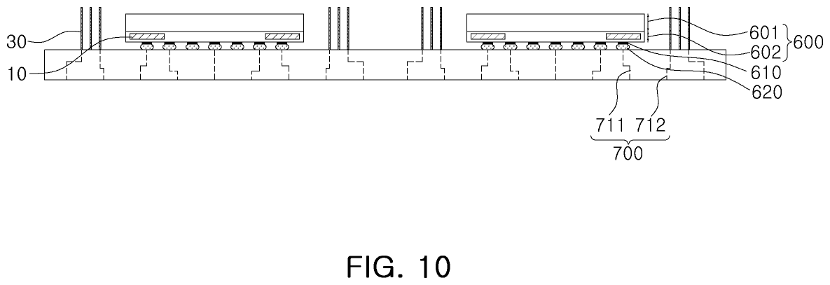

FIGS. 10 to 15 are cross-sectional views schematically illustrating a manufacturing process of a semiconductor package according to an example embodiment.

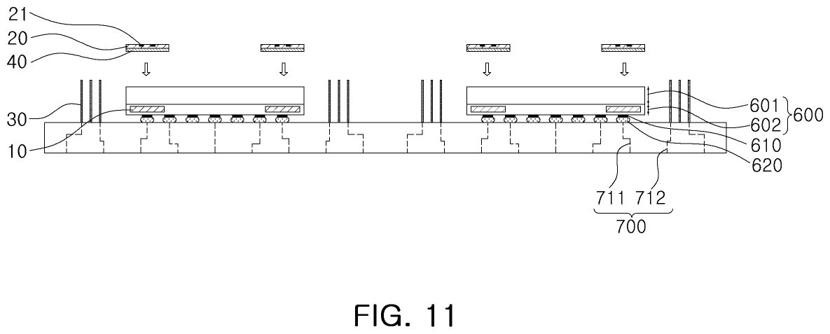

Referring to FIG. 10, a ‘second preliminary package structure’ may be provided in a face-down form in the same or similar manner as that of FIG. 4. The second preliminary package structure may include a package substrate 700 that includes first and second wirings 711 and 712 and extends laterally, and in the second preliminary package structure, a plurality of logic chips 600 including the first wireless communication element 10 may be disposed on one surface of the package substrate 700 to be electrically connected to the first wiring 711. The conductive vertical structures 30 may be formed to be electrically connected to the second wiring 712 of the package substrate 700. The conductive vertical structures 30 may be pillar-shaped structures, and in this case, the conductive vertical structures 30 may be formed to extend in a direction perpendicular to the upper surface of the package substrate 700. The upper surface level of the conductive vertical structures 30 may be formed to be higher than the upper surface level of the logic chip 600. Referring to FIG. 11, the difference between the upper surface levels of the conductive vertical structures 30 and the logic chip 600 may be the thickness of the adhesive layer 40 disposed on one side of the logic chip 600.

Referring to FIG. 11, the second wireless communication elements 20 may be mounted on the logic chip 600 to overlap at least a portion of the logic chip 600. In this case, the adhesive layer 40 may be provided while being formed on the lower surface of the second wireless communication elements 20, but the present inventive concept is not limited thereto. For example, the adhesive layer 40 may be provided while being formed on at least a portion of the upper surface of the logic chip 600. The second wireless communication elements 20 may be adhered to at least a portion of the upper surface of the logic chip 600 by the adhesive layer 40, to overlap the first wireless communication element 10.

In some embodiments, upper surfaces of the second wireless communication elements 20 may be at the same vertical level as upper surfaces of the conductive vertical structures 30. For example, upper surfaces of the second wireless communication elements 20 and the conductive vertical structures 30 may be coplanar.

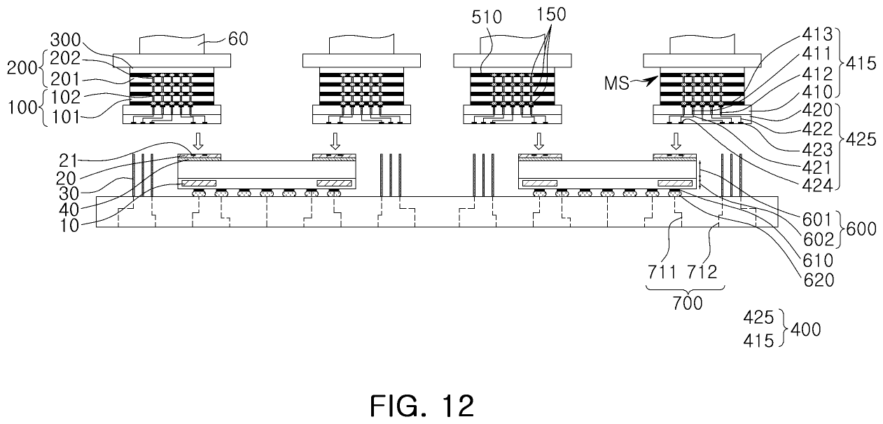

Referring to FIG. 12, chip structures MS may be placed on the second wireless communication elements 20 by the bonding head 60. In detail, the second lower pads 424 of which lower surfaces are exposed may be placed in contact with the front pads 21 of which upper surfaces are exposed. When the second lower pads 424 and the front pads 21 are formed of copper (Cu), a temperature of 300° C. to 500° C. or lower is applied to form copper (Cu)-copper (Cu) bonding between the lower surfaces of the second lower pads 424 and the upper surfaces of the front pads 21.

The chip structures MS may be placed on the conductive vertical structure 30 by the bonding head 60. In detail, the first lower pads 423, whose lower surfaces are exposed, may be placed to contact the upper surfaces of the conductive vertical structures 30. Similarly, when the first lower pads 423 and the conductive vertical structures 30 are copper (Cu), by applying a temperature of 300° C. to 500° C. or less, copper (Cu)-copper (Cu) bonding may be formed between the lower surfaces of the first lower pads 423 and the upper surfaces of the conductive vertical structures 30.

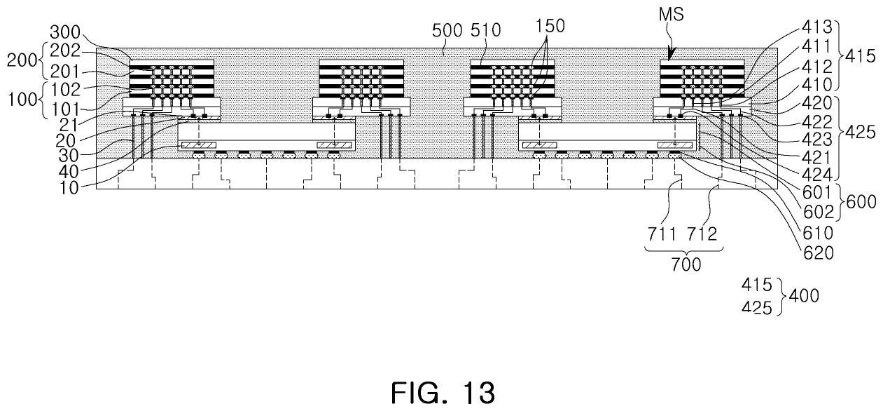

Referring to FIG. 13, on the package substrate 700, an encapsulant 500 surrounding a logic chip 600, a plurality of chip structures (MS), a plurality of conductive vertical structures 30, an adhesive layer 40, and the second wireless communication elements 20 may be disposed.

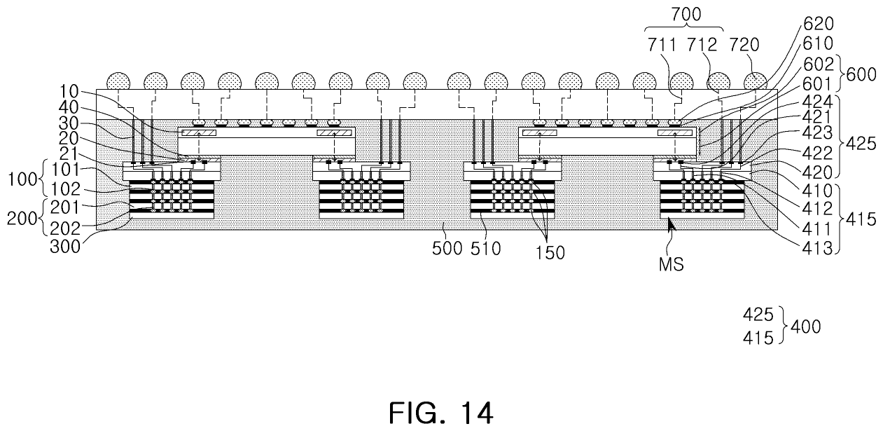

Referring to FIG. 14, the ‘second preliminary package’ surrounded by the encapsulant 500 may be provided to be face-up, and external connection terminals 720 that are electrically connected to the first and second wirings 711 and 712 of the package substrate 700 may be attached.

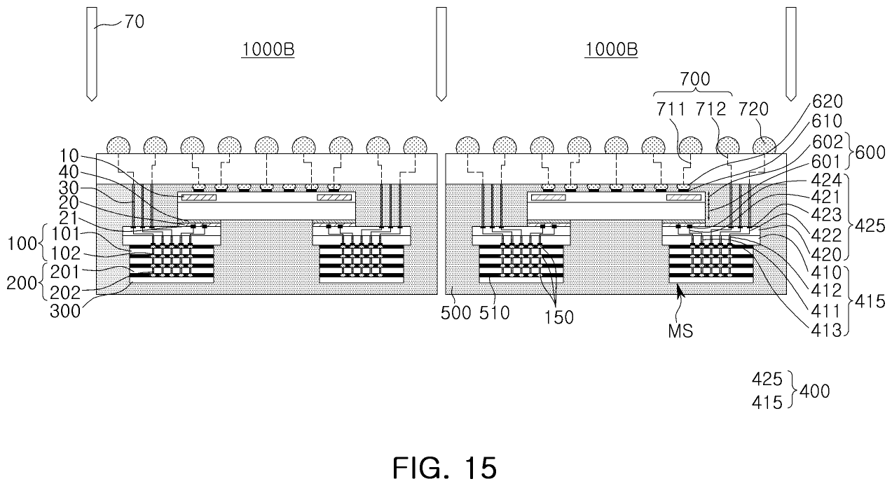

Referring to FIG. 15, the back-side of the package substrate 700 may be cut in a vertical direction using the cutter 70, and may be separated into a plurality of semiconductor packages 1000B.

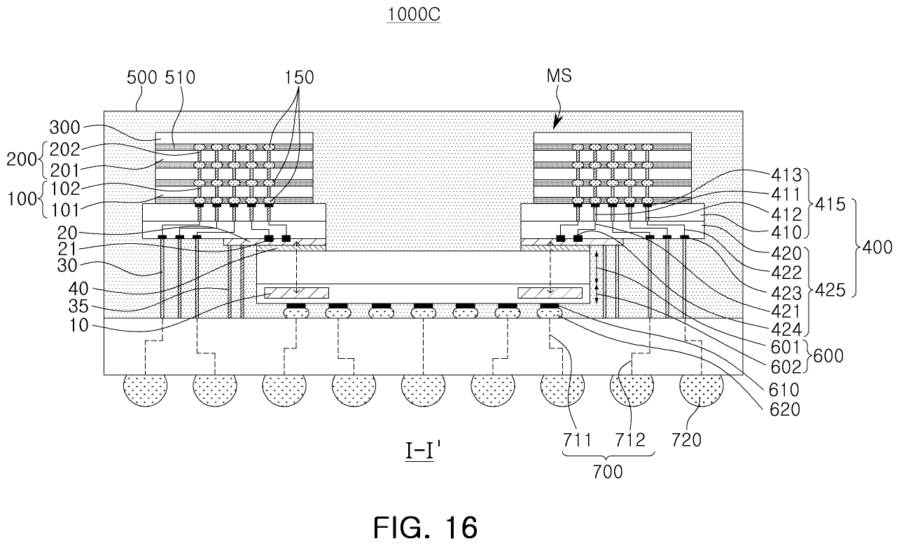

FIG. 16 is a cross-sectional view illustrating a semiconductor package 1000C according to an example embodiment.

Referring to FIG. 16, the semiconductor package 1000C of an example embodiment may have the same features as those described with reference to FIGS. 1, 2, and 9, except that a second wireless communication element 20 extends in a direction toward the conductive vertical structures 30 or away from the center of the logic chip 600.

The second wireless communication element 20 of this embodiment may be a semiconductor chip on which patterns for wireless communication are formed. The second wireless communication element 20 of this embodiment may extend in a direction toward the plurality of conductive vertical structures 30 or in a direction away from the center of the logic chip 600. In detail, one side of the second wireless communication element 20 of this embodiment may extend to protrude further than one side of the logic chip 600. In other words, one side of the second wireless communication element 20 and one side of the logic chip 600 may have a step difference.

The second wireless communication element 20 of this embodiment may include a second conductive pattern (not illustrated) that transmits and receives signals with a first conductive pattern (not illustrated) of the first wireless communication element 10. In this case, the second conductive pattern is disposed in a portion that does not protrude from one side of the logic chip 600, and may be disposed to face the first conductive pattern.

A plurality of support structures 35 may be disposed between a portion of the second wireless communication element 20 that protrudes from one side of the logic chip 600 and the package substrate 700. Each of the plurality of support structures 35 may extend vertically from the upper surface of the package substrate 700 to the lower surface of the portion of the second wireless communication element 20 that protrudes from one side of the logic chip 600. The plurality of support structures 35 may serve to support the second wireless communication element 20 protruding from the side of the logic chip 600. The support structures 35 may be pillar-type structures. The upper surface level of the support structures 35 may be formed to be higher than the upper surface level of the logic chip 600. The difference between the upper surface levels of the support structures 35 and the logic chip 600 may be the thickness of the adhesive layer 40 disposed on one side of the logic chip 600. The upper surface level of the conductive vertical structures 30 may be formed to be higher than the upper surface level of the support structures 35. The difference in the upper surface level of the conductive vertical structures 30 and the support structures 35 may be the thickness of the second wireless communication element 20 disposed on the support structures 35. The plurality of support structures 35 may include a material similar to a material of the plurality of conductive vertical structures 30, but the present inventive concept is not limited thereto.

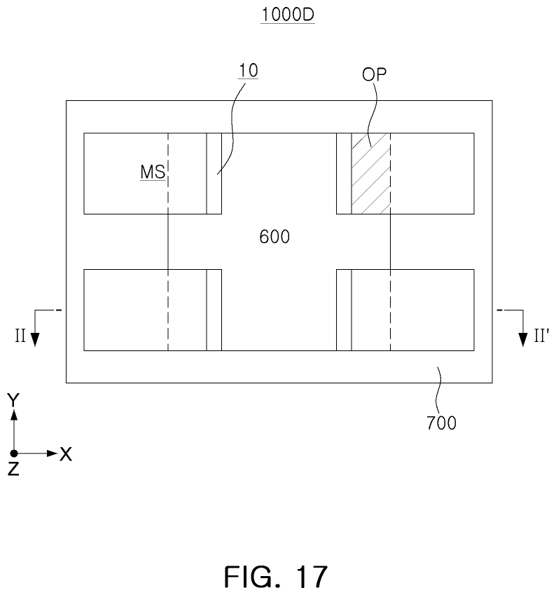

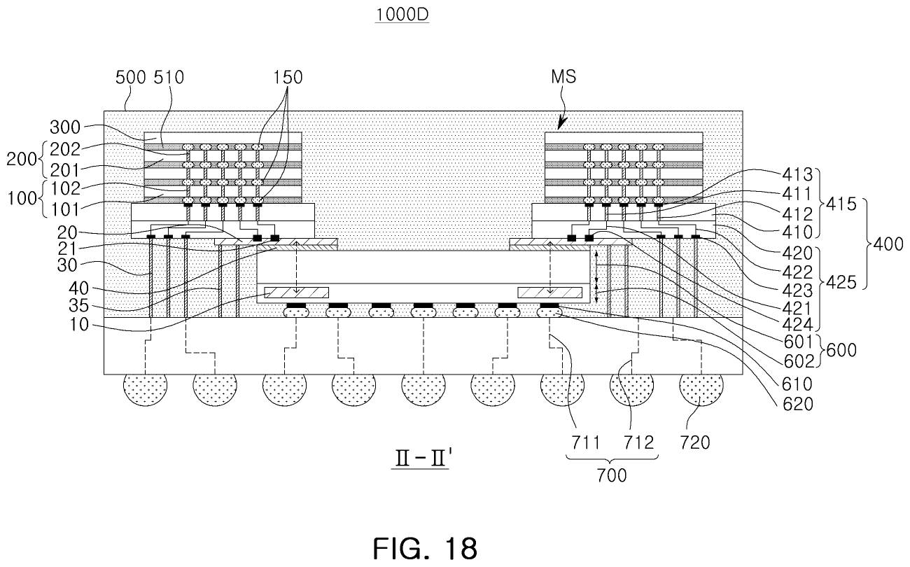

FIG. 17 is a top view of a semiconductor package 1000D according to an example embodiment. FIG. 18 is a cross-sectional view illustrating a section taken along line II-II′ of FIG. 17.

Referring to FIGS. 17 and 18, the semiconductor package 1000D of an example embodiment may have the same features as those described with reference to FIG. 16, except that a second wireless communication element 20 extends in a direction away from a plurality of conductive vertical structures 30 or in a direction toward the center of the logic chip 600.

The second wireless communication element 20 of this embodiment may be a semiconductor chip on which patterns for wireless communication are formed. The second wireless communication element 20 of this embodiment may extend in a direction away from the plurality of conductive vertical structures 30 or toward the center of the logic chip 600. In detail, one side of the second wireless communication element 20 of this embodiment may extend to protrude further than one side of the chip structure MS. In other words, one side of the second wireless communication element 20 and one side of the chip structure MS may have a step difference.

As described with reference to FIG. 16, the wireless communication semiconductor chip may include a second conductive pattern (not illustrated) that transmits and receives signals with a first conductive pattern (not illustrated) of the first wireless communication element 10. In this case, the second conductive pattern may be disposed on a portion that does not protrude from one side of the logic chip 600 and one side of the chip structure MS, and may be disposed to face the first conductive pattern.

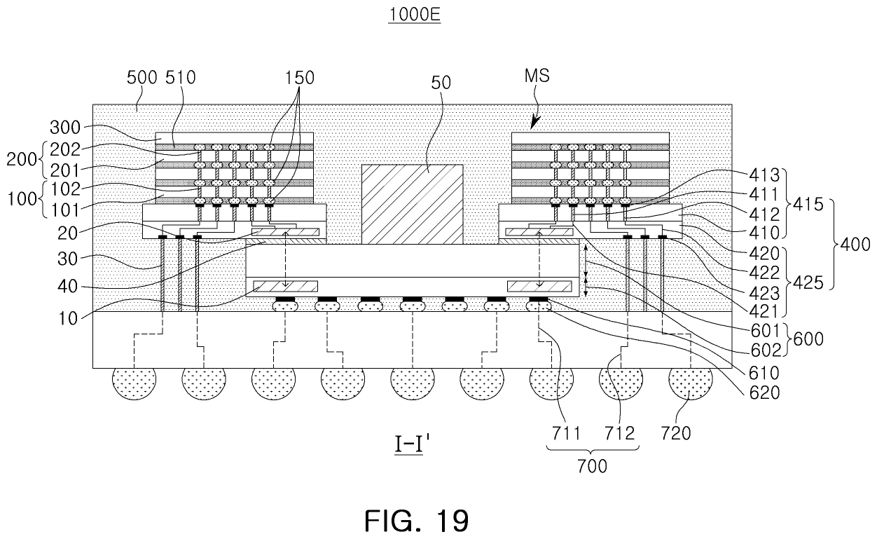

FIG. 19 is a cross-sectional view illustrating a semiconductor package 1000E according to an example embodiment.

Referring to FIG. 19, the semiconductor package 1000E of an example embodiment may include a package substrate 700, at least one chip structure (MS), a logic chip 600, and a heat dissipation structure 50. The package substrate 700, at least one chip structure (MS), and logic chip 600 may have the same or similar characteristics as the semiconductor package 1000 described with reference to FIGS. 1 and 2. For reference, the semiconductor packages 1000A, 1000B, 1000C, and 1000D described with reference to FIGS. 3, 9, 16, and 18 may also include a heat dissipation structure 50.

The semiconductor package 1000E of an example embodiment may include the heat dissipation structure 50 with high thermal conductivity. The heat dissipation structure 50 may be disposed on the logic chip 600. The heat dissipation structure 50 may effectively discharge heat generated from the logic chip 600 toward the top (or toward the upper surface of the ‘encapsulant 500’).

The heat dissipation structure 50 may be formed of a material with higher thermal conductivity than the encapsulant 500. For example, the heat dissipation structure 50 may include copper (Cu), but is not limited thereto. For example, the heat dissipation structure 50 may include a metal such as nickel (Ni), gold (Au), silver (Ag), aluminum (Al), tungsten (W), titanium (Ti), tantalum (Ta), indium (In), molybdenum (Mo), manganese (Mn), cobalt (Co), tin (Sn), magnesium (Mg), rhenium (Re), beryllium (Be), gallium (Ga), ruthenium (Ru), or the like, or alloys thereof.

As set forth above, according to example embodiments, by disposing heterogeneous chips, for example, a logic chip and a memory chip, to overlap, a semiconductor package advantageous in miniaturization and having improved performance may be provided.

While example embodiments have been illustrated and described above, it will be apparent to those skilled in the art that modifications and variations could be made without departing from the scope of the present inventive concept as defined by the appended claims.

What is claimed is:

1. A semiconductor package comprising:
a package substrate including a first wiring and a second wiring;
a logic chip on the package substrate, electrically connected to the first wiring of the package substrate, and including a first wireless communication element;
a chip structure on the logic chip, and including a buffer chip containing a first through-electrode, a second through-electrode, a first connection circuit electrically connected to the first through-electrode, and a second connection circuit electrically connected to the second through-electrode, and a plurality of memory chips stacked on the buffer chip and electrically connected to the first and second through-electrodes;
a second wireless communication element within the buffer chip or between the buffer chip and the logic chip, electrically connected to the first connection circuit, and coupled to the first wireless communication element; and
a plurality of conductive vertical structures between the chip structure and the package substrate and electrically connecting the second connection circuit and the second wiring.

2. The semiconductor package of claim 1, wherein in a top view, at least a portion of the first wireless communication element and at least a portion of the second wireless communication element are located within an area in which a portion of the chip structure and a portion of the logic chip overlap.

3. The semiconductor package of claim 1, wherein the buffer chip includes a first layer including the first and second through-electrodes, and a second layer disposed below the first layer and including the first and second connection circuits.

4. The semiconductor package of claim 3,
wherein the first layer includes a semiconductor substrate surrounding the first and second through-electrodes and containing silicon, and
wherein the second layer includes an insulating layer surrounding the first and second connection circuits and including at least one of silicon oxide and silicon nitride.

5. The semiconductor package of claim 1,
wherein the first wireless communication element includes a first conductive pattern, and
wherein the second wireless communication element includes a second conductive pattern connected to the first conductive pattern through inductive coupling or capacitive coupling.

6. The semiconductor package of claim 1,
wherein the logic chip further includes a first region, a second region disposed below the first region and including an integrated circuit, and a third region disposed above the first region and including the first wireless communication element, and
wherein the logic chip further includes a third through-electrode penetrating through the first region and electrically connecting the first wireless communication element and the integrated circuit.

7. The semiconductor package of claim 1,
wherein the second wireless communication element is disposed within the buffer chip, and
wherein the semiconductor package further includes an adhesive layer between a portion of the chip structure and a portion of the logic chip.

8. The semiconductor package of claim 7, wherein an upper surface of the adhesive layer and upper surfaces of the conductive vertical structures are on the same level.

9. The semiconductor package of claim 1,
wherein the second wireless communication element is disposed between the buffer chip and the logic chip, and
wherein the semiconductor package further includes an adhesive layer disposed between a portion of the logic chip and a portion of the second wireless communication element.

10. The semiconductor package of claim 9,
wherein the buffer chip further includes a lower surface pad electrically connected to the first connection circuit, and
wherein the second wireless communication element further includes a front pad in direct contact with the lower surface pad of the buffer chip.

11. The semiconductor package of claim 9, wherein an upper surface of the second wireless communication element and upper surfaces of the conductive vertical structures are on the same level.

12. The semiconductor package of claim 9,
wherein one side of the second wireless communication element extends in a direction of the conductive vertical structures, the one side of the second wireless communication element and one side of the logic chip have a step difference from each other, and
wherein the semiconductor package further includes a support structure between a lower surface of the second wireless communication element and the package substrate.

13. The semiconductor package of claim 9, wherein one side of the second wireless communication element extends toward a center of the logic chip, the one side of the second wireless communication element and one side of the chip structure have a step difference.

14. The semiconductor package of claim 1, further comprising an encapsulant covering at least portions of the logic chip, the chip structure, the conductive vertical structures, and the package substrate, respectively.

15. A semiconductor package comprising:
a chip structure including a buffer chip containing a first through-electrode, a second through-electrode, first lower surface pads, and a first connection circuit electrically connecting the second through-electrode and the first lower surface pads, and a plurality of memory chips stacked on the buffer chip and electrically connected to the first through-electrode and the second through-electrode;
a logic chip below the buffer chip to expose the first lower surface pads;
a package substrate below the buffer chip and the logic chip, and including a first wiring electrically connected to the logic chip and a second wiring electrically connected to the buffer chip;
a first wireless communication element disposed within the chip structure or between the chip structure and the logic chip, and electrically connected to the first through-electrode;
a second wireless communication element within the logic chip and coupled to the first wireless communication element;
an encapsulant covering at least portions of the chip structure, the logic chip, and the package substrate respectively; and
a plurality of conductive vertical structures extending within the encapsulant and electrically connecting the first lower surface pads and the second wiring.

16. The semiconductor package of claim 15,
wherein the first wireless communication element includes a first conductive pattern, and
wherein the second wireless communication element includes a second conductive pattern transmitting and receiving a signal with the first conductive pattern.

17. The semiconductor package of claim 16,
wherein the first wireless communication element is disposed within the buffer chip, and
wherein the buffer chip further includes a second connection circuit electrically connecting the first through-electrode and the first conductive pattern of the first wireless communication element.

18. The semiconductor package of claim 16,
wherein the first wireless communication element is disposed between the buffer chip and the logic chip,
wherein the buffer chip further includes second lower surface pads and a second connection circuit electrically connecting the first through-electrode and the second lower surface pads, and
wherein the first wireless communication element further includes front pads in contact with the second lower surface pads.

19. A semiconductor package comprising:
a package substrate including a first wiring and a second wiring;
a logic chip on the package substrate and electrically connected to the first wiring of the package substrate;
a chip structure on the logic chip, and including a memory circuit, and a first through-electrode and a second through-electrode electrically connected to the memory circuit;
a first wireless communication element disposed within the logic chip;
a second wireless communication element below the chip structure, electrically connected to the first through-electrode, and overlapping the first wireless communication element in a vertical direction; and
a conductive vertical structure electrically connecting the second through-electrode of the chip structure and the second wiring of the package substrate.

20. The semiconductor package of claim 19, further comprising a heat dissipation member on the logic chip and spaced apart from the chip structure.
